(19) United States
(12) Patent Application Publication
(10) Pub. No.: US 2007/0164301 A1
(43) Pub. Date: Jul. 19, 2007

(54) Light-emitting device with improved light-emitting brightness

(76) Inventor: Ming-Der Lin, Chu Tung Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/333,370

(22) Filed: Jan. 18, 2006

(51) Int. Cl. H01L 33/00

(52) U.S. Cl. 257/98

(57) ABSTRACT

A light-emitting device with improved light-emitting brightness comprises a first electrode and a second electrode on the upper surface of a light emitting element. On the positions opposite to the first electrode and the second electrode, a first power supply electrode and a second power supply electrode are provided on the partial upper surface of a power supply substrate. A reflective layer is provided between the first power supply electrode, the second power supply electrode and power supply substrate. A eutectic layer is used to firmly provide the light emitting element on the power supply substrate such that the first electrode and second electrode can be electrically connected to corresponding first power supply electrode and second power supply electrode, and thus protecting structural feature of the reflective layer and maintaining the reflective efficiency of the reflective layer. Furthermore, by reducing the vertical distance between the light emitting element and power supply substrate by the eutectic layer, an object of improving the brightness of the light emitting device is then achieved.

### FIELD OF THE INVENTION

The present invention is related to a light-emitting device, and more particularly to a light-emitting element with improved light-emitting brightness. Not only is to protect structural feature of the reflective layer for maintaining the reflective efficiency of the reflective layer, but reduce the vertical distance between the light emitting element and power supply substrate by the eutectic layer, so as to improve the brightness of the light emitting device.

### BACKGROUND

Since light-emitting diode (LED) providing with advantages of long lifetime, small volume, little consuming power, fast reacting speed, no radiation, and monochromatic emitting, it is widely applied in the products, such as indicating lamps, advertising boards, traffic signal lights, vehicle lights, display panels, communication appliances, consumer electronics, etc.

Please refer to FIG. 1, shows a structural cross section of a prior art light emitting device. A light emitting element 11 comprises a light transmittance substrate 113, a first material layer 111 is provided on the upper surface of the light transmittance substrate 113, and a second material layer 112 is further provided on the partial upper surface of the first material layer 111. A PN junction with generating a color light source is naturally formed between the first material layer 111 and second material layer 112. Further, a reflective layer 17 is further provided on the upper surface of the second material layer 112, and a first electrode 114 is provided on the partial upper surface of the first material layer 111 without providing the second material layer 112, while a second electrode 116 is also provided on a partial surface of the reflective layer 17. The first electrode 114 and second electrode 116 can be respectively electrically connected to the first power supply electrode 131 and second power supply electrode 132 of a power supply substrate 13 by tin balls 115 and 117. In a prior art light emitting device structure, the light emitting element can be used to reflect back light L2 generated by the PN junction because of providing a reflective layer 17. Therefore, the projective light source generated by the light emitting element 11 can at least comprise the front light L1 and back light L2 to thus improve the brightness of the light emitting element 11.

However, some high temperature heat treatment procedures are often needed in the following procedures after finishing fixing the reflective layer 17 by the light emitting element 11, such as forming the second electrode 116. The calorific capacity of the high temperature heat treatment will conducts to the reflective layer 17. At this time, the structure or feature of the reflective layer 17 will be easily destroyed because of high temperature contact. Alternatively, the high temperature causes metallic material molecules in some tin balls 117 entering the reflective layer 17 such that the reflectivity of the reflective layer 17 descends to further affect the derivative of the back light L2 generated by the PN junction and the entire light emitting brightness of the light emitting device.

In addition, the reflective layer 17 is firmly provided on the second material layer 112. It is more difficult in manufacturing. Besides, to choose the reflective layer 17 and second material layer 112 to have better lattice structural similarity and electric conductivity, the material types which can be chosen for the reflective layer 17 are also limited.

### SUMMARY OF THE INVENTION

Accordingly, how to design a novel light-emitting device which can protect structural feature of the reflective layer and maintain the reflective efficiency of the reflective layer, and also improve the brightness of the light emitting device against shortcomings of above mentioned prior art technology is then achieved is the key point of the present invention.

It is a primary object of the present invention to provide a light-emitting device with improved light-emitting brightness which can resolve technical difficulties faced by the above mentioned prior art light-emitting device.

It is a secondary object of the present invention to provide a light-emitting device with improved light-emitting brightness whose reflective layer is firmly provided on the conductive substrate instead of firmly provided in the light emitting element such that the light source emitted from the light emitting element can directly be guided by the reflective layer and project to a proper direction, such as side light source, to effectively improve the light emitting efficiency and light emitting brightness of the light emitting device.

It is another object of the present invention to provide a light-emitting device with improved light-emitting brightness whose reflective layer is directly firmly provided on a power supply substrate to thus simplify following manufacturing of the reflective layer and substantially increase selectable types of the materials of the reflective layer.

It is another object of the present invention to provide a light-emitting device with improved light-emitting brightness which firmly provides the light emitting element on a power supply substrate by a eutectic layer. By the low thickness feature of the eutectic layer, a vertical distance between the light emitting element and power supply substrate is reduced. Not only can the working high temperature of the light emitting element be effectively eliminated to ensure reliability and use lifetime of the light emitting element, but also the difficulty in a ball mount procedure of a prior art tin ball.

It is another object of the present invention to provide a light-emitting device with improved light-emitting brightness of whose light emitting element the first electrode and second electrode locate near the same level position to thus be beneficial in proceeding the following procedures.

Therefore, to achieve the above mentioned object, the present invention provides a light-emitting device with improved light-emitting brightness mainly providing at least one reflective layer on the upper surface of a power supply substrate, a power supply electrode further providing on the partial upper surface of the reflective layer, and the power supply electrode electrically connected to a light emitting element by a eutectic layer.

Further, to achieve the above mentioned object, the present invention further provides a light-emitting device with improved light-emitting brightness mainly providing at least one reflective layer on the upper surface of a power supply substrate, at least one power supply electrode further providing on the partial upper surface of the reflective layer, and the power supply electrode electrically connected to a light emitting element by a bound layer.

Further, to achieve the above mentioned object, the present invention further provides a light-emitting device with improved light-emitting brightness mainly providing a power supply electrode on the upper surface of a power supply substrate, and the power supply electrode electrically connected to a light emitting element by a eutectic layer.

### BRIEF DESCRIPTION OF DRAWINGS

FIG. 1 is a structural cross section of a prior art light emitting device.

FIG. 2 is a structural cross section of an embodiment of a light-emitting device of the present invention.

FIG. 3 is a structural cross section of an embodiment of a light-emitting device of the present invention.

FIG. 4A is a structural cross section of another embodiment of a light-emitting device of the present invention.

FIG. 4B is a vertical view of a power supply substrate of the embodiment as shown in FIG. 4A of the present invention.

FIG. 5 is a structural cross section of another embodiment of the present invention.

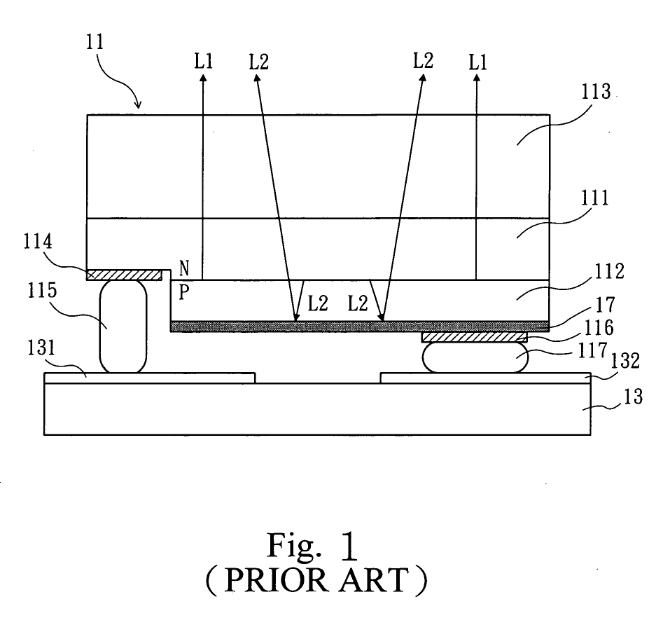

### DETAILED DESCRIPTION

The structural features and the effects to be achieved may further be understood and appreciated by reference to the presently preferred embodiments together with the detailed description.

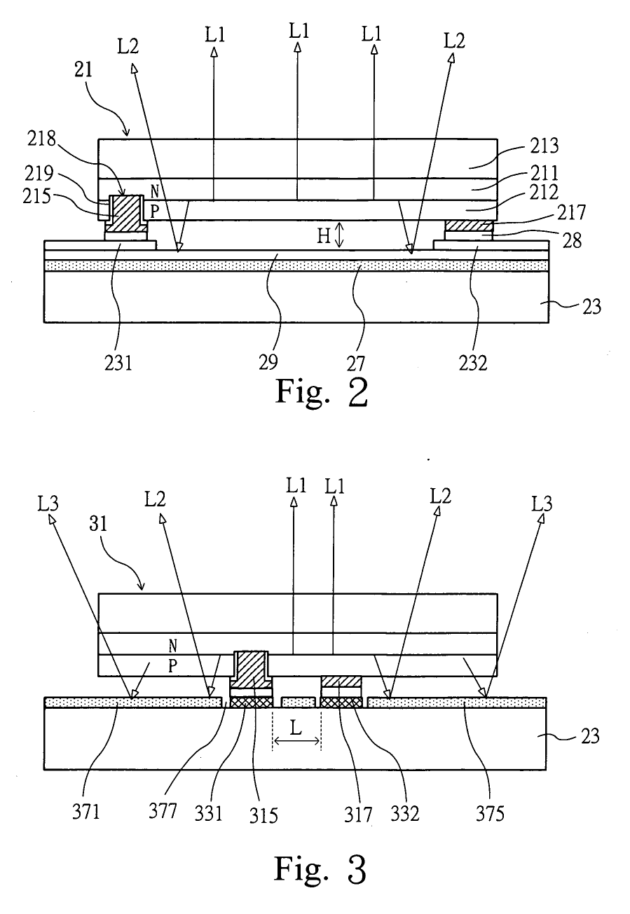

Firstly, please refer to FIG. 2, a structural cross section of an embodiment of a light emitting device with improved light emitting brightness of the present invention. As shown, the light emitting device with improved light emitting brightness of the present invention mainly comprises a light emitting element 21 and a power supply substrate 23. Among them, a reflective layer 27 is provided on an upper surface of the power supply substrate 23. If the reflective layer 27 is made of a conductive material, a light transmittance isolative layer 29 can be further provided on an upper surface of the reflective layer 27, or as shown in FIG. 3, an isolative gap (375) is provided to isolate two sides of reflective layers (371, 375). On the other hand, if the reflective layer 27 is made of an isolative material, a light transmittance isolative layer 29 is not formed. A first power supply electrode 231 and second power supply electrode 232 are respectively provided on a partial upper surface of the light transmittance isolative layer 29 (or reflective layer 27).

Further, the light emitting element 21 mainly comprises a light transmittance substrate 213, a first material layer 211 is provided on an upper surface of the light transmittance substrate 213, and a second material layer 212 is further provided on an upper surface of the first material layer 211. A PN junction which can generate a color light source can be naturally formed between the first material layer 211 and second material layer 212. An extensive fillister 218 which can pass through the second material layer 212 and partial volume of the first material layer 211 is dug. An inner surface of the extensive fillister 218 and a partial upper surface of the second material layer 212 connectedly provide an isolative layer 219. A first electrode 215 is provided on a surface of the isolative layer 219, and the first electrode 215 can be electrically connected to the first material layer 211. Further, a corresponding second electrode 217 is provided on a partial surface of the other side of the second material layer 212, and the first electrode 215 and second electrode 217 can be electrically connected to corresponding first power supply electrode 231 and second power supply electrode 232 on the power supply substrate 23 via a bound layer 28, respectively.

The reflective layer 27 can be used to reflect a back light L2 generated by the PN junction such that a projective light source generated by the light emitting element 21 at least can comprised a front light L1 and back light L2 to thus achieve an object of improve the light emitting brightness of the light emitting element 21.

Since the reflective layer 27 of the present invention is directly firmly provided on the upper surface of the power supply substrate 23, different from the prior art structure directly firmly providing it on the second material layer 212, thus an abuse of destroying the structural integrity of the reflective layer 27 of the light emitting element 21 due to working high temperature in following procedures can be effectively reduced to maintain the reflectivity of the light source and improve the light emitting brightness.

Of course, since the reflective layer 27 is directly firmly provided on the power supply substrate 23, the process is simple in opposition to firmly providing the reflective layer on the surface of the second material layer of the prior art. Besides, the choices of the material can also be variety. Conductive materials or non-conductive materials are both suitable. Therefore, the inventive object of the present invention can be achieved.

Further, since the first electrode 215 and second electrode 217 has similar or the same level height, they can be easily placed and connected to the first power supply electrode 231 and second power supply electrode 232 via the bound layer 28, instead of using tin balls with various sizes as a conductive bound layer, as in the prior art light emitting devices of flip chip structures. Therefore, it is very beneficial to proceed the following procedures.

To this end, the bound layer 28 of the present invention can be selected as a tin ball or a eutectic layer. If the bound layer 28 is selected from an eutectic material, a vertical distance H between the upper surface of the light emitting element 21 and the upper surface of the power supply substrate 23 can be reduced to less than 50 um, even preferably to less than 10 um, less than the height of the prior art structural tin ball, about 100 um. In this way, the operating distance of high temperature conduction can be effectively reduced to conveniently and quickly eliminate the working high temperate of the light emitting element 21 to the conductive substrate 23 or external world by the eutectic layer 28 to thus increase the light emitting reliability and use lifetime of the light emitting element 21. Besides, the operating width of the eutectic layer 28 can be adjusted anytime to smaller than the width of the tin ball to thus broaden the operating area of the reflective layer 27 and the light emitting brightness of the light emitting device.

The light emitting element 21 of the present invention can be selected as a nitride, such as InGaN, GaN, or AlGaInN, etc., or can also be selected as a quaternary compound or a ternary compound, such as GaAsP, AlGaAs, or AlGaInP.

Moreover, please refer to FIG. 3, a structural cross section of a preferred embodiment of the light emitting device of the present invention. As shown, in the embodiment, the reflective layers 371, 375 of the power supply substrate 23 are not placed between the first power supply electrode 331, second power supply electrode 332, and power supply substrate 23 as previous embodiment, rather respectively firmly provided on the partial upper surface of the power supply substrate 23 which is not covered by the first power supply electrode 331 and second power supply electrode 332. An isolative gap 375 can be provided between both reflective layers 371, 375. Further, the first power supply electrode 331 and second power supply electrode 332 will be placed near the central position of the light emitting element 31. In a preferred embodiment, both level distance L can be reduced to about 100 um. The positions of the first electrode 315 and second electrode 317 of the light emitting element 31 can also be changed oppositely. In this way, the light emitting element 31 can generate more back side light L3 by operating the reflective layers 371, 375 to achieve the object of improving the light emitting brightness of the light emitting device.

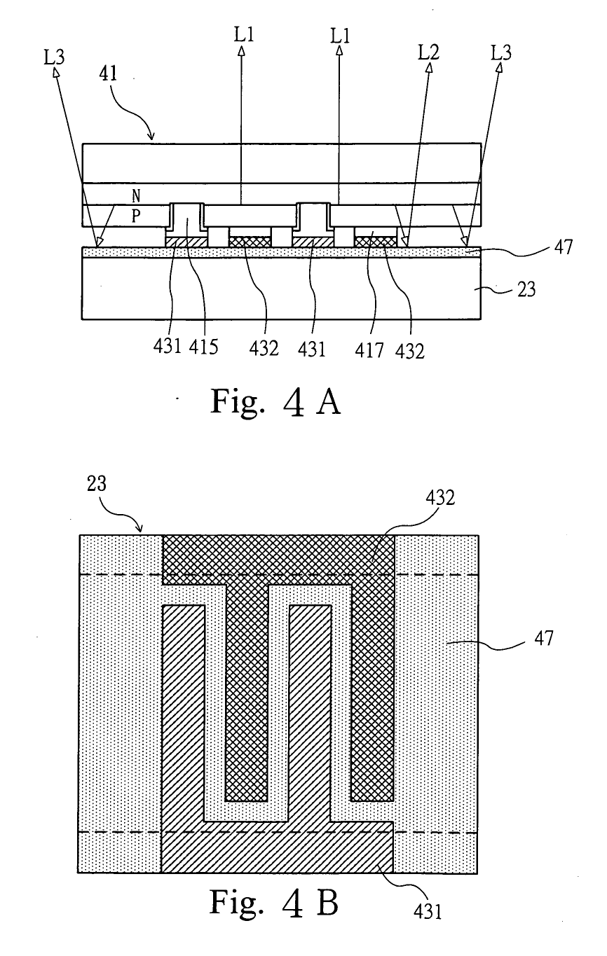

Next, please refer to FIG. 4A and FIG. 4B, respectively a structural cross section and a vertical view of the power supply substrate of another embodiment of the light emitting device of the present invention. As shown, in the present embodiment, the reflective layer 47 is made of a non-conductive material whose upper surface has a plurality of first power supply electrodes 431 and second power supply electrodes 432. The arranged amount and positions of the first electrode 415 and second electrode 417 of the light emitting element 41 are also correspondingly changed to thus broaden the evenly distributing ability of working current to improve the working efficiency and light emitting brightness of the light emitting element 41.

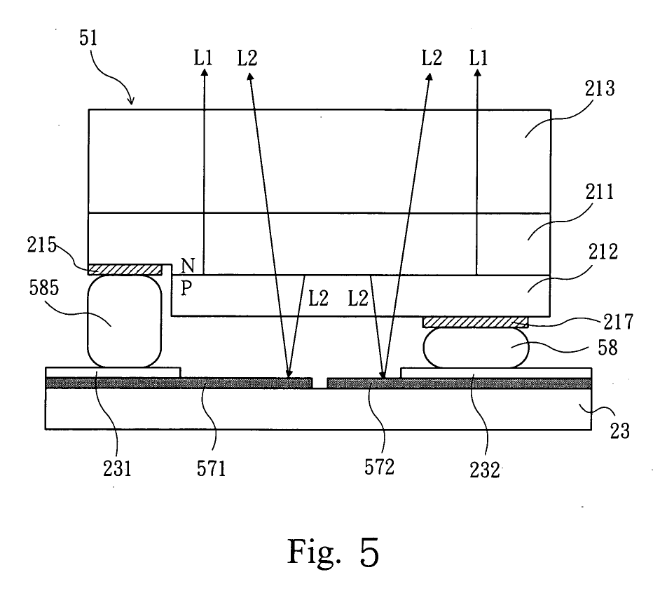

Finally, please refer to FIG. 5, a structural cross section of another embodiment of the light emitting device of the present invention. As shown, in the embodiment, the light emitting element of the previous embodiment is changed to a prior art flat panel light emitting element 51. The second material layer 212 is only provided on the partial upper surface of the first material layer 211. A first electrode 215 is provided on the partial upper surface of the first material layer 211 which is mot covered by the second material layer 212. A second electrode 217 is correspondingly provided on the partial upper surface of the other side of second material layer 212. The first electrode 215 and second electrode 217 of the light emitting element 51 are electrically connected to the corresponding first power supply electrode 231 and second power supply electrode 232 on the power supply substrate 23 by a bound layer (such as tin ball).

Reflective layers 571, 572 are respectively provided between the first power supply electrode 231, second power supply electrode 232, and power supply substrate 23. The reflective layers 571, 572 are made of a conductive material, and thus needed to be isolated from each other. However, by placing the reflective layers 571, 572 on the power supply substrate 23, the object of being beneficial to the following procedures and improving the light emitting brightness of the light emitting device can be achieved.

Of course, although in the previous embodiments, two power supply electrodes are described on the power supply substrate; however, in various embodiments, the power supply can also be one or plural to match various types of light emitting elements. For example, if the light emitting device is not of a flip chip structure, a power supply electrode and a bound layer can only be provided on the power supply substrate and electrically connected to a bottom electrode of a light emitting element. The top electrode of the light emitting element can be electrically connected to another power supply circuit.

In summary, it should be appreciated that the present invention is related to a light-emitting device and more particularly to a light-emitting element with improved light-emitting brightness. Not only is structural feature of the reflective layer protected and is the reflective efficiency of the reflective layer maintained, but also by reducing the vertical distance between the light emitting element and power supply substrate by the eutectic layer to achieve an object of improving the brightness of the light emitting device.

The foregoing description is merely one embodiment of present invention and not considered as restrictive. All equivalent variations and modifications in process, method, feature, and spirit in accordance with the appended claims may be made without in any way from the scope of the invention.

1. A light-emitting device with improved light-emitting brightness comprising at least one reflective layer provided on the upper surface of a power supply substrate, a power supply electrode further provided on the partial upper surface of said reflective layer, and said power supply electrode electrically connected to a light emitting element by an eutectic layer.

2. The light-emitting device according to claim 1, wherein said light emitting element comprises a light transmittance substrate, a first material layer provided on the upper surface of said light transmittance substrate, a second material layer provided on the partial upper surface of said first material layer, and a PN junction for generating a color light source naturally formed between said first material layer and said second material layer; a first electrode electrically connected to one of said first material layer and said power supply electrode provided at a side of said second material layer, and a second electrode which electrically connected to one of said second material layer and said power supply electrode provided at said other side of said second material layer.

3. The light-emitting device according to claim 1, wherein a light transmittance isolative layer is further provided between said power supply electrode and said reflective layer.

4. The light-emitting device according to claim 3, wherein said reflective layer is made of a material with electric conductivity.

5. The light-emitting device according to claim 1, wherein said light emitting element is selectively made of a material of one of a ternary or quaternary compound and nitride material.

6. The light-emitting device according to claim 2, wherein said light emitting element further comprises at least one extensive fillister passing through said second material layer and partial first material layer, wherein said extensive fillister and on a partial surface of said second material layer is provided an isolative layer, and said first electrode is provided on the surface of said isolative layer.

7. The light-emitting device according to claim 6, wherein said first electrode and said second electrode are closely provided on the central point of said light emitting element.

8. The light-emitting device according to claim 7, wherein said first electrode and said second electrode is less than 100 um distance.

9. The light-emitting device according to claim 2, wherein said second material layer and said power supply substrate is less than 50 μm of the vertical distance.

10. The light-emitting device according to claim 9, wherein said vertical distance is preferably less than 10 μm.

11. A light-emitting device with improved light-emitting brightness comprising at least one reflective layer provided on the upper surface of a power supply substrate, at least one power supply electrode provided on the partial upper surface of said reflective layer, and said power supply electrode electrically connected to a light emitting element by a bound layer.

12. The light-emitting device according to claim 11, wherein said bound layer is selectively as one of a tin ball and a eutectic layer.

13. The light-emitting device according to claim 11, wherein a light transmittance isolative layer is further provided between said first power supply electrode, said second power supply electrode, and said reflective layer.

14. A light-emitting device with improved light-emitting brightness comprises at least one power supply electrode provided on the upper surface of a power supply substrate, and said power supply electrode electrically connected to a light emitting element by a eutectic layer.

15. The light-emitting device according to claim 14, wherein said s light-emitting element and said power supply substrate is less than 50 μm of a vertical distance.

16. The light-emitting device according to claim 15, wherein said vertical distance is preferably less than 10 μm.
